(19) United States
(12) Patent Application Publication
(10) Pub. No.: US 2026/0370227 A1
(43) Pub. Date: Nov. 19, 2026

(54) POWER SUPPLY DEVICE AND METHOD OF CONTROLLING POWER SUPPLY DEVICE

(71) Applicant: LITE-ON TECHNOLOGY CORPORATION, Taipei (TW)

(72) Inventor: Shin-Li LIN, Taipei (TW)

(21) Appl. No.: 19/562,881

(22) Filed: Mar. 11, 2026

Related U.S. Application Data
(60) Provisional application No. 63/806,806, filed on May 16, 2025.

(30) Foreign Application Priority Data
Jan. 30, 2026 (CN) 202610131661.0

(51) Int. Cl. H03K 19/00; H02H 1/00; H04L 12/10

(52) U.S. Cl. CPC H03K 19/0016; H02H 1/0007; H02H 1/0061; H04L 12/10

(57) ABSTRACT

In an aspect of the disclosure, a power supply device is provided. The power supply device includes a power supply module including a control circuit and selectively coupled to a power receiving device for controlling a power supplied to the power receiving device. The power supply device also includes a logic circuit including a first input terminal and a first output terminal and coupled to the control circuit via the first input terminal and the first output end. When the first output terminal outputs a switching signal to the control circuit, the control circuit is activated. When the first input terminal receives a power supply signal from the control circuit, the control circuit is maintained turning on and supplying power to the power receiving device.

### CROSS REFERENCE TO RELATED APPLICATION

This application claims the benefit of US provisional application Serial No. 63/806,806, filed May 16, 2025, and the benefit of China application serial No. 202610131661.0, filed Jan. 30, 2026, subject matters of which are incorporated herein by reference.

### TECHNICAL FIELD

The disclosure relates in general to power supply devices and methods of controlling power supply device, and more particularly, to techniques of switching switches of the control circuit of the power supply device by an logic circuit.

### BACKGROUND

Currently, low-energy-consumption techniques have become a global research focus. The aim is to reduce energy consumption while maintaining or improving performance, thereby achieving energy conservation.

However, in conventional power supply systems, the power supply device needs to remain activation to detect the presence of a connected device when no load is applied. This increases energy consumption during no-load scenarios, failing to achieve the goal of energy conservation.

Therefore, how to reduce the energy consumption of the power supply device during no-load scenarios while simultaneously detecting connection status of the connected device has become an urge issue for the industry.

### SUMMARY

The techniques provided by the present disclosure uses a logic circuit to switch the power supply module on and off, so that the power supply module detects whether the power receiving device is connected when it is turned on intermittently. Therefore, the control circuit of the power supply module operates intermittently (alternately turns on or off) when there is no load (no power is supplied to the power receiving device or no power receiving device is connected), which can reduce the power consumption of the power supply device when there is no load.

The first aspect of the present disclosure features a power supply device. The power supply device includes a power supply module including a control circuit and selectively coupled to a power receiving device for controlling a power supplied to the power receiving device. The power supply device also includes a logic circuit including a first input terminal and a first output terminal and coupled to the control circuit via the first input terminal and the first output end. When the first output terminal outputs a switching signal to the control circuit, the control circuit is controlled to be operated. When the first input terminal receives a power supply signal from the control circuit, the control circuit is maintained turning on and supplying power to the power receiving device.

The second aspect of the present disclosure features a method of controlling a power supply device including a power supply module and a logic circuit. The method includes controlling, by the logic circuit, a switching signal output to a control circuit of the power supply module for operating the power supply module alternately. The method also includes, when the switching signal is high, turning on the control circuit and determining, by the control circuit, whether a power receiving device is coupled to the power supply module. The method also includes, upon determining that the power receiving device is coupled to the power supply module, controlling, by the control circuit, the power supply module to supply power to the power receiving device and output a power supply signal to the logic circuit. The method also includes, when the logic circuit receives the power supply signal, controlling the switching signal output to the control circuit to keep at high level.

The details of one or more disclosed implementations are set forth in the accompanying drawings and the description below. Other features, aspects, and advantages will become apparent from the description, the drawings and the claims.

### BRIEF DESCRIPTION OF THE DRAWINGS

FIG. 1 is a function block diagram illustrating a power supply device according to some implementations of the present disclosure.

FIG. 2 is a timing diagram illustrating operations of a switching signal and a power supply signal of the power supply device according to some implementations of the present disclosure.

FIGS. 3A-3C are timing diagrams illustrating various operations of switching signal, power supply signal, protection signal, first alert unit and the second alert unit of the power supply device according to some implementations of the present disclosure.

FIG. 4 is a flowchart illustrating a procedure of controlling the power supply device according to some implementations of the present disclosure.

In the following detailed description, for purposes of explanation, numerous specific details are set forth in order to provide a thorough understanding of the disclosed implementations. It will be apparent, however, that one or more implementations may be practiced without these specific details. In other instances, well-known structures and devices are schematically shown in order to simplify the drawing.

### DETAILED DESCRIPTION

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used to describe the illustrative implementations but, like the illustrative implementations, should not be used to limit the present disclosure. The elements included in the illustrations herein may not be drawn to scale.

FIG. 1 is a functional block diagram illustrating a power supply device 100 according to some implementations of the present disclosure. The power supply device 100 includes a power supply module 110, a logic circuit 120, a first alert unit 131 and a second alert unit 132. The first alert unit 131 and the second alert unit 132 can be LEDs (Light Emitting Diodes) of different colors. The power supply module 110 includes a control circuit 111 and a connection port 112. The control circuit 111 is electrically connected to the connection port 112. When a power receiving device 200 is connected to the connection port 112, the control circuit 111 can control the power supply device 100 and the power receiving device 200 to establish communication (for example, through a handshaking mechanism), and, after establishing communication, to supply power to the power receiving device 200 through the connection port 112.

Specifically, the power supply device 100 can be a PSE (Power Sourcing Equipment) in Power over Ethernet (PoE); the power receiving device 200 can be a PD (Powered Device) in Power over Ethernet (PoE); the control circuit 111 can be a PSE (Power Sourcing Equipment) controller chip, such as the MP3921 of Monolithic Power Systems (MPS)); the connection port 112 can be an RJ45 port. It should be noted that PSE equipment for Power over Ethernet in the prior art includes a control circuit, such as a control chip, for communication and detecting whether the powered device (PD) is connected to Power over Ethernet (PoE), thereby supplying power to the powered device (PD). Therefore, when the powered device is not connected, the control circuit or control chip of the power supply device in the prior art still needs to operate to detect whether the powered device is connected to the power supply device, which increases energy consumption in no-load (no power is supplied to the powered device) scenarios. Furthermore, the DoE VII (Department of Energy Level VII) specification requires power supply devices with an output of less than 250W to consume less than 150mW when there is no load. Therefore, in this case, conventional power supply devices related to Power over Ethernet (PoE) consume at least 200mW when control circuit or control chip is turned on for long periods, and cannot meet the DoE VII specification. Therefore, the power supply device 100 of the present disclosure is able to meet the DoE VII specification through the description of the following embodiments.

In some implementations, the logic circuit 120 includes a first output terminal 121a, a second output terminal 121b, a third output terminal 121c, a first input terminal 122a and a second input terminal 122b. The first output terminal 121a, the first input terminal 122a and the second input terminal 122b are coupled to the control circuit 111, and respectively receive a power supply signal PS and a protection signal PTS from the control circuit 111, and output a switching signal SW to the control circuit 111. Specifically, the logic circuit 120 can be a Complex Programmable Logic Device (CPLD), such as the GreenPAK series of Renesas Electronics Corporation, in which the control circuit 111 includes protection functions, such as overcurrent protection (OCP), short-circuit protection (SCP), overvoltage protection (OVP), undervoltage protection (UVP) or overtemperature protection (OTP), and a protection signal PTS is transmitted when the protection functions above are triggered.

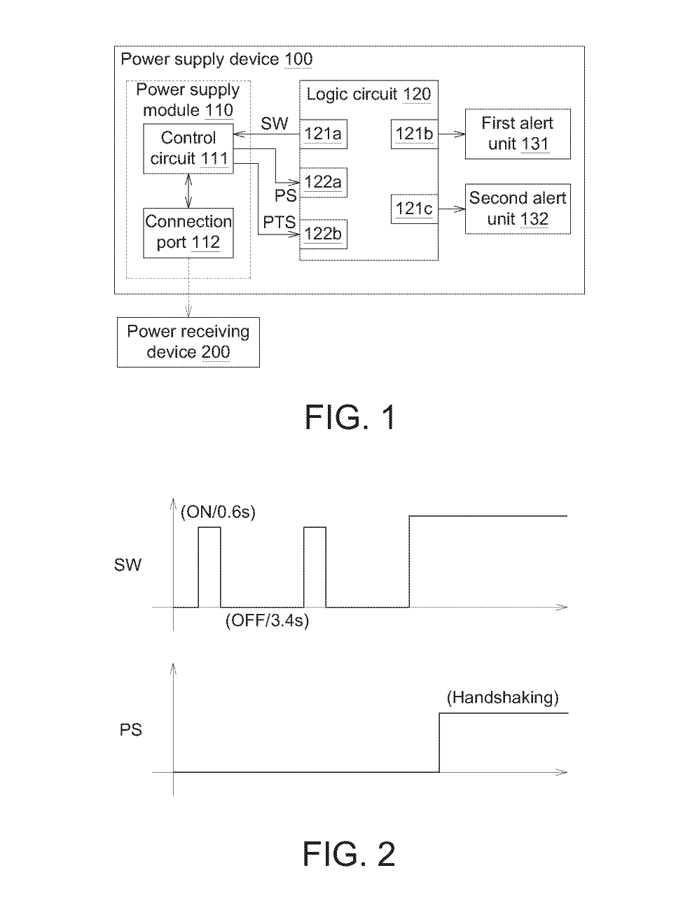

Next, referring to FIG. 2 simultaneously, FIG. 2 is a timing diagram illustrating operations of a switching signal SW and a power supply signal PS of the power supply device 100 according to some implementations of the present disclosure. When the power supply device 100 has no load (no power receiving device is connected to the connection port 112), the logic circuit 120 controls the switching signal SW to be alternately output at a high level and a low level for alternately turning on or off the control circuit 111. For example, when the switching signal SW is at the low level, the control circuit 111 is turned off, and when the switching signal SW is at the high level, the control circuit 111 is turned on. This can prevent the control circuit 111 from being turned on for long periods without load, thereby reducing the energy consumption of the power supply device 100. In some implementations, when the switching signal SW controlled by the logic circuit 120 is output alternately at the high level or the low level, the duration ratio of the high level and the low level is about 3:17, that is, the duration of the high level is shorter than the duration of the low level. For example, the duration of the high level is 0.6 seconds, and the duration of the low level is 3.4 seconds, as shown in FIG. 2. The example durations above are not limitations and can be set according to requirements. Generally, the time required for the power supply device 100 and the power receiving device 200 to establish communication (for example, through a handshaking mechanism) is about 0.4 seconds. Therefore, when the high level of the switching signal SW is 0.6 seconds, the control circuit 111 that is turned on has enough time to detect or determine whether the power receiving device 200 is coupled to the connection port 112 at this time. When the activated control circuit 111 determines that no power receiving device 200 is coupled to the connection port 112, the logic circuit 120 continues to control the switching signal SW to be output alternately at the high level or the low level for alternately turning on or off the control circuit 111, thereby reducing the energy consumption of the power supply device 100.

When the activated control circuit 111 determines that a power receiving device 200 is coupled to the connection port 112, the control circuit 111 establishes communication with the power receiving device 200, controls the connection port 112 to supply power to the power receiving device 200, and outputs the power supply signal PS (or switches the power supply signal PS to a high level, as shown in FIG. 2) to the logic circuit 120. When the logic circuit 120 receives the power supply signal PS (or a high-level power supply signal PS), the switching signal SW is controlled to remain at the high level, as shown on the right side of FIG. 2. At this time, the power supply device 100 can maintain the communication and power supply relationship with the power receiving device 200, and the control circuit 111 continues to output the power supply signal PS (or switches the power supply signal PS to the high level) to the logic circuit 120, so that the logic circuit 120 controls the switching signal SW to maintain the high level, that is, the control circuit 111 continues to turn on.

When the power receiving device 200 is disconnected from the power supply device 100, that is, when control circuit 111 determines that the power receiving device 200 is no longer coupled to the connection port 112, the control circuit 111 controls the connection port 112 to stop supplying power and stop outputting the power supply signal PS to the logic circuit 120 (or switch the power supply signal PS to the low level). When the logic circuit 120 does not receive the power supply signal (or switches the power supply signal PS to the low level), the logic circuit 120 controls the output switching signal SW to return to an alternate high level or low level to alternately turn on or off the control circuit 111 to reduce energy consumption of the power supply device 100. Therefore, the switching signal SW controlled by the logic circuit 120 is output alternately at the high level or the low level to alternately turn on or off the control circuit 111. For example, when the high level is 0.6 seconds and the low level is 3.4 seconds, the energy consumption of the power supply device 100 can be reduced to less than 50mW, or about 33.6mW, so that the power consumption of the power supply device 100 is less than 150mW when there is no load, which is in compliance with the DoE VII specification.

For the DoE VII specification, the power supply device 100 provided by the present disclosure further includes a first alert unit 131 (for example, a red LED indicator light) for indicating a protection status of the power supply device 100, and a second alert unit 132 (for example, a white LED indicator light) for indicating a connection status of the power supply device 100. The second input terminal 122b of the logic circuit 120 is coupled to the control circuit 111 for receiving a protection signal PTS from the control circuit 111. The protection signal PTS is a signal output to the logic circuit when the control circuit 111 detects an overvoltage or overcurrent condition in the power supply module 110 (for example, obtained by comparing the reference voltage/current with the actual detected internal voltage/current) when there is a load (for example, when supplying power to the power receiving device 200). The second output terminal 121b and the third output terminal 121c of the logic circuit 120 are coupled to the first alert unit 131 and the second alert unit 132 respectively, and are used to control the first alert unit 131 and/or the second alert unit 132 to turn on or off according to the protection signal PTS and the power supply signal PS.

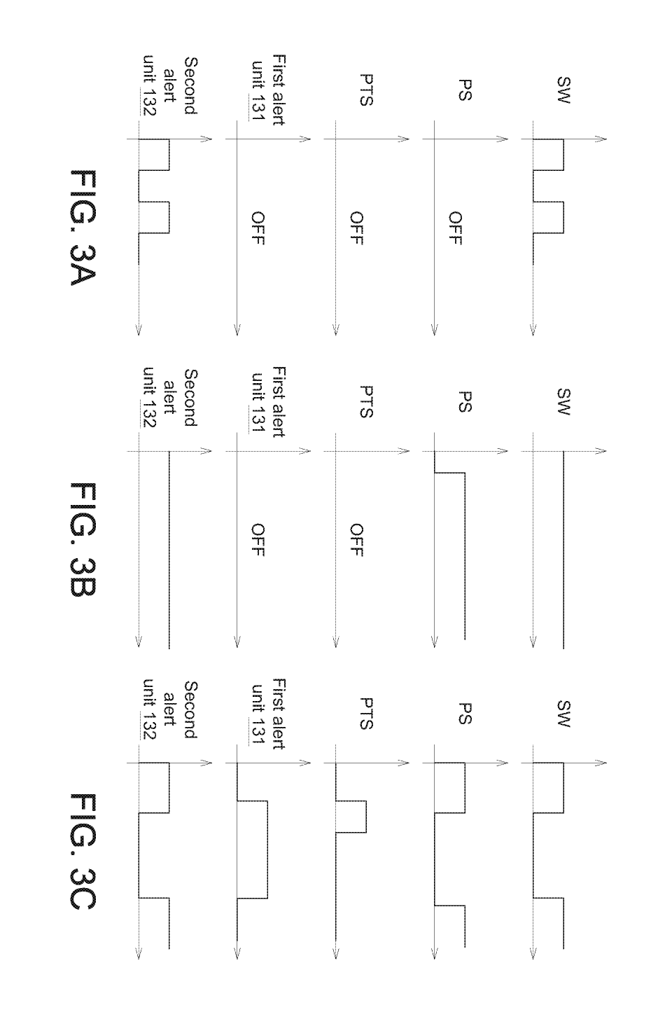

Referring to FIGS. 1 and 3A - 3C simultaneously, FIGS. 3A - 3C are timing diagrams illustrating various operations of switching signal SW, power supply signal PS, protection signal PTS, first alert unit 131 and the second alert unit 132 of the power supply device 100 according to some implementations of the present disclosure. When the power supply device 100 has no load, that is, when the control circuit 111 does not provide the power supply signal PS (or the power supply signal PS is at the low level) to the logic circuit 120, as discussed above, the logic circuit 120 controls the switching signal SW to be alternately output at the high level and the low level, and simultaneously controls the second alert unit 132 to alternately turn on or off, and keeps the first alert unit 131 off, as shown in FIG. 3A. It can be understood that, in this example, since the power supply device 100 has no load, the control circuit 111 will not provide the protection signal PTS to the logic circuit 120.

In the example of FIG. 3B, when the switching signal SW is at the high level, the control circuit 111 is turned on, and the control circuit 111 determines that the powered receiving device 200 is connected. As discussed above, after establishing communication with the power receiving device 200 and without an overcurrent or overvoltage condition (the control circuit 111 does not provide the protection signal PTS or the protection signal PTS is at the low level), the control circuit 111 starts to provide the power supply signal PS (or switches the power supply signal PS to the high level) to the logic circuit 120. The logic circuit 120 keeps the switching signal SW at the high level according to the power supply signal PS, and simultaneously controls the second alert unit 132 to turn on (or to remain at the high level) and keeps the first alert unit 131 to turn off (corresponding to no protection signal PTS or the protection signal PTS being at the low level), as shown in FIG. 3B.

In the example of FIG. 3C, when the power supply device 100 is connected to the power receiving device 200 (with a load), that is, after the control circuit 111 determines that the power receiving device 200 is connected and establishes communication with the power receiving device 200, and when the control circuit 111 detects the occurrence of overcurrent or overvoltage, the control circuit provides the protection signal PTS (or switches the protection signal PTS to the high level) to the logic circuit 120, to shut down the communication or electrical connection with the power receiving device 200 and stop providing the power supply signal PS (or switches the power supply signal PS to the low level) to the logic circuit 120. The logic circuit 120 controls the first alert unit 131 to turn on for a predetermined time duration (for example, 1 second, 2 seconds or 3 seconds) according to the received protection signal PTS, to remind the user that an overcurrent or overvoltage status occurs in the power supply device 100. At the same time, the logic circuit 120 controls the switching signal SW to be alternately output at the high level and the low level to alternately turn on or off the control circuit 111 to re-establish communication with the power receiving device 200 until communication with the power receiving device 200 is successfully established. In this example, the control of turning on or off the second alert unit 132 also corresponds to the switching timing of the switching signal SW, as shown in FIG. 3C.

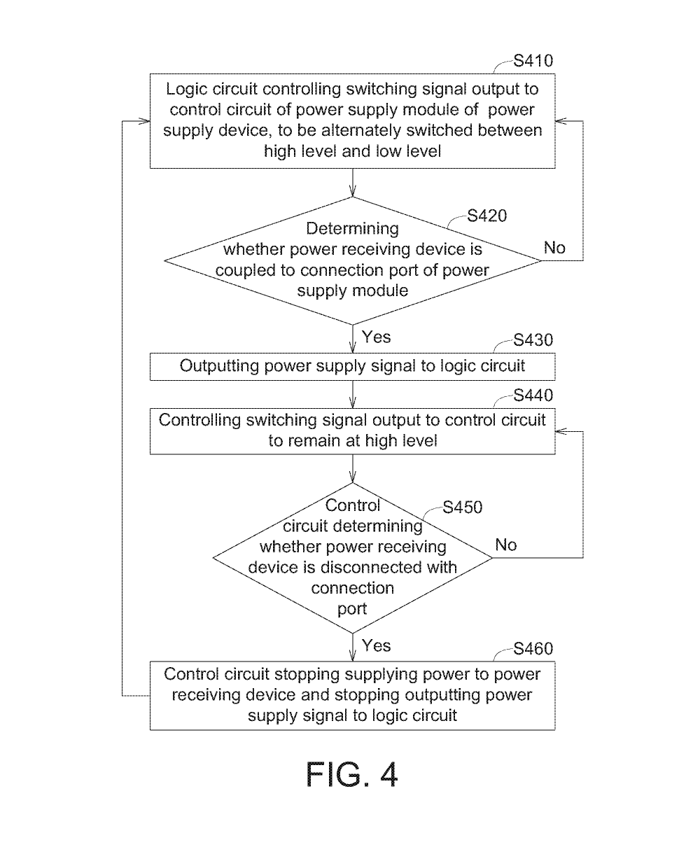

FIG. 4 is a flowchart illustrating a procedure of controlling a power supply device (such as the power supply device 100 in FIG. 1) according to some implementations of the present disclosure. In step S410, for example, the logic circuit 120 of FIG. 1 controls a switching signal (such as the switching signal SW) output to the control circuit (such as the control circuit 111 of power supply module 110 in FIG. 1) of the power supply module of the power supply device, to be alternately switched between a high level and a low level, thereby alternately turning the power supply module on or off.

In step S420, when the switching signal is at the high level, the activated control circuit determines whether the power receiving device (such as the power receiving device 200 in FIG. 1) is coupled to a connection port (such as the connection port 112 in FIG. 1) of the power supply module. If it is determined that there is no power receiving device coupled to the connection port of the power supply module, the procedure returns to step S410.

Upon determining that there is a power receiving device coupled to the connection port, the procedure proceeds to step S430, whereby the control circuit controls the connection port to supply power to the power receiving device and outputs a power supply signal (such as the power supply signal PS) to the logic circuit.

In step S440, when the logic circuit receives the power supply signal, the logic circuit controls the switching signal output to the control circuit to remain at the high level, thereby keeping the control circuit activated and communicating with and supplying power to the power receiving device.

In step S450, the control circuit determines whether the power receiving device is disconnected with the connection port. If not, the procedure returns to step S440.

Upon determining that the power receiving device is disconnected with the connection port, the procedure proceeds to step S460, where the control circuit stops supplying power to the power receiving device and stops outputting the power supply signal to the logic circuit. Then, the procedure returns to step S410 and repeats the above steps.

As described above, the techniques provided by the present disclosure, which uses a logic circuit to output a switching signal to alternately turn the control chip or control circuit for the power receiving device on or off, and detects whether the power receiving device is connected when the control circuit is on, eliminates the need for the power supply device to be continuously powered on. Thus, the control chip or control circuit of the power supply device does not need to be continuously activated when there is no load (no power supply to the power receiving device or no power receiving device connected), making the power consumption of the power supply device under no-load scenarios significantly lower than the conventional techniques of continuously activating the control chip or control circuit of the power supply device to detect whether, for example, a power receiving device connected via Ethernet is connected. This allows the power supply device to comply with DoE VII specification; for example, a power supply device with an output of less than 250W using the techniques of the present disclosure consumes less than 50mW under no-load scenarios. Furthermore, different LEDs can be controlled by the logic circuit to indicate the protection status and/or connection status of the power supply device for the DoE VII specification.

The present disclosure and examples thereof can be implemented as one or more computer program products, for example, one or more modules of computer program instructions encoded on a computer-readable medium are executed by a data processing device or control the operation of the data processing device. The computer-readable medium may be a machine-readable storage device, a machine-readable storage substrate, a memory device, or a combination thereof. The term "data processing device" includes all means, apparatus, and machines for processing data, including, for example, a programmable processor, a computer, or multiple processors or computers. In addition to hardware, this means may include program code that establishes the execution environment of the computer program in question, such as program code constituting processor firmware, a protocol stack, a database management system, an operating system, or a combination thereof.

A computer program (also known as a program, software, software disclosure, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in a plurality of coordinated files (e.g., files that store one or more modules, sub programs, or portions of code).A computer program can be deployed for execution on one computer or on a plurality of computers that are located at one site or distributed across a plurality of sites and interconnected by a communications network.

The processes and logic flows described in this document can be performed by one or more programmable processors executing one or more computer programs to perform the functions described herein. The processes and logic flows can also be performed by, and apparatus can also be implemented as, special purpose logic circuitry, e.g., an FPGA (field programmable gate array) or an ASIC (application specific integrated circuit).

Processors, processing units, engines, and accelerators suitable for the execution of a computer program include, by way of example, both general and special purpose microprocessors, and any one or more processors of any kind of digital computer. Generally, a processor, a processing unit, an engine, or an accelerator will receive instructions and data from a read only memory or a random access memory or both. The essential elements of a computer can include a processor, a processing unit, an engine, or an accelerator for performing instructions and one or more memory devices for storing instructions and data. Generally, a computer can also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data can include all forms of nonvolatile memory, media and memory devices, including by way of example semiconductor memory devices, e.g., EPROM, EEPROM, and flash memory devices; magnetic disks. The processor, the processing unit, the engine, or the accelerator and the memory can be supplemented by, or incorporated in, special purpose logic circuitry, such as other processors, processing units, engines, or accelerators.

While this document may describe many specifics, these should not be construed as limitations on the scope of an invention that is claimed or of what may be claimed, but rather as descriptions of features specific to particular implementations. Certain features that are described in this document in the context of separate implementations can also be implemented in combination in a single embodiment. Conversely, various features that are described in the context of a single embodiment can also be implemented in a plurality of implementations separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made according to what is disclosed.

What is claimed is:

1. A power supply device, comprising:
a power supply module, comprising a control circuit and selectively coupled to a power receiving device for controlling a power supplied to the power receiving device; and
a logic circuit, comprising a first input terminal and a first output terminal and coupled to the control circuit via the first input terminal and the first output terminal,
wherein, when the first output terminal outputs a switching signal to the control circuit, the control circuit is activated,
wherein, when the first input terminal receives a power supply signal from the control circuit, the control circuit is maintained turning on and supplying power to the power receiving device.

2. The power supply device of claim 1, wherein the power supply module further comprises a connection port, and the power supply module is selectively coupled to the power receiving device through the connection port,
wherein the logic circuit controls the switching signal to be alternately output at a high level and a low level,
wherein, when the switching signal is at the low level, the control circuit is turned off, and, when the switching signal is at the high level, the control circuit is turned on and determines whether the power receiving device is coupled to the connection port.

3. The power supply device of claim 2, wherein the logic circuit controls the switching signal to be alternately output at the high level and the low level, and a duration of the high level is shorter than a duration of the low level.

4. The power supply device of claim 2, wherein, upon the control circuit determining that the power receiving device is coupled to the connection port, the control circuit controls the connection port to supply power to the power receiving device and outputs the power supply signal to the logic circuit, so that when the logic circuit receives the power supply signal, the switching signal is controlled to be kept at the high level.

5. The power supply device of claim 2, wherein, upon determining that the power receiving device is not coupled to the connection port, the control circuit controls the connection port to stop supplying power to the power receiving device and stop outputting the power supply signal to the logic circuit, so that when the logic circuit does not receive the power supply signal, the logic circuit controls the switching signal to be alternately output at the high level and the low level.

6. The power supply device of claim 1, further comprising:
a first alert unit, coupled to the logic circuit and configured to indicate a protection status of the power supply device; and
a second alert unit, coupled to the logic circuit and configured to indicate a connection status of the power supply device.

7. The power supply device of claim 6, wherein, when the logic circuit receives the power supply signal from the control circuit and does not receive a protection signal from the control circuit, the logic circuit controls the second alert unit to be turned on and the first alert unit to be turned off,
wherein, when the logic circuit does not receive the power supply signal and the protection signal, the logic circuit controls the switching signal to be alternately output at the high level or the low level, and controls the second alert unit to be alternately turned on and off.

8. The power supply device of claim 6, wherein, when the control circuit is coupled to the power receiving device and outputs a protection signal, the control circuit shuts off an electrical connection with the power receiving device for stopping outputting the power supply signal,
wherein, when the logic circuit receives the protection signal, the logic circuit controls the first alert unit to turn on for a predetermined time, and the switching signal to be alternately output at the high level and the low level.

9. A method of controlling a power supply device including a power supply module and a logic circuit, the method comprising:
controlling, by the logic circuit, a switching signal output to a control circuit of the power supply module to operate the power supply module;
when the switching signal is high, turning on the control circuit and determining, by the control circuit, whether a power receiving device is coupled to the power supply module;
upon determining that the power receiving device is coupled to the power supply module, controlling, by the control circuit, the power supply module to supply power to the power receiving device and output a power supply signal to the logic circuit; and
when the logic circuit receives the power supply signal, controlling the switching signal output to the control circuit to keep at high level.

10. The method of claim 9, wherein the logic circuit controls the switching signal to be alternately output at the high level and a low level for alternately turning the power supply module on or off, and a duration of the high level is shorter than a duration of the low level.

11. The method of claim 9, further comprising:
upon determining that the power receiving device is not coupled to a connection port of the power supply module, controlling, by the control circuit, the connection port to stop supplying power to the power receiving device and stop outputting the power supply signal to the logic circuit, so that when the logic circuit does not receive the power supply signal, the logic circuit controls the switching signal to be alternately output at the high level and the low level.

12. The method of claim 9, further comprising:
indicating, by a first alert unit coupled to the logic circuit of the power supply device, a protection status of the power supply device; and
indicating, by a second alert unit coupled to the logic circuit of the power supply device, a connection status of the power supply device.

13. The method of claim 12, further comprising:
when the logic circuit receives the power supply signal from the control circuit and does not receive a protection signal from the control circuit, controlling, by the logic circuit, the second alert unit to be turned on and the first alert unit to be turned off,
wherein, when the logic circuit does not receive the power supply signal and the protection signal, the logic circuit continues to control the switching signal to be alternately output at the high level and the low level, and controls the second alert unit to be alternately turned on and off.

14. The method of claim 12, further comprising:
outputting, by the control circuit, a protection signal to the logic circuit, and shutting off an electrical connection with the power receiving device for stopping outputting the power supply signal; and
when the logic circuit receives the protection signal, controlling, by the logic circuit, the first alert unit to be turned on for a predetermined time, and the switching signal to be alternately output between the high level and the low level.
